(19) United States
(12) Patent Application Publication
(10) Pub. No.: US 2020/0107456 A1
(43) Pub. Date: Apr. 2, 2020

(54) CIRCUIT BOARD STRUCTURE

(71) Applicant: BOARDTEK ELECTRONICS CORPORATION, TAOYUAN CITY (TW)

(72) Inventor: CHIEN-CHENG LEE, TAOYUAN CITY (TW)

(21) Appl. No.: 16/355,624

(22) Filed: Mar. 15, 2019

(30) Foreign Application Priority Data
Sep. 28, 2018 (TW) 107213236

(51) Int. Cl. H05K 3/42; H05K 3/12; H05K 1/11

(52) U.S. Cl. CPC H05K 3/429; H05K 3/0026; H05K 1/115; H05K 3/1275

(57) ABSTRACT

A circuit board structure includes a multi-layer board, a conductive body, and an electroplated layer. The multi-layer board has a predetermined conductive layer embedded therein, and includes a first blind hole recessed in a board surface thereof so as to allow a part of the predetermined conductive layer to be exposed therefrom. The first blind hole has an aperture having a diameter within a range of 0.15-0.5 mm, and has an aspect ratio defined as M that is within a range of 1.5-10. The conductive body is filled in the first blind hole and is electrically coupled to the part of the predetermined conductive layer. An inner surface of the conductive body defines a second blind hole having an aspect ratio that is larger than 0 and is less than M. The electroplated layer is formed in the second blind hole and is connected to the inner surface.

### CROSS-REFERENCE TO RELATED PATENT APPLICATION

This application claims the benefit of priority to Taiwan Patent Application No. 107213236, filed on Sep. 28, 2018. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a circuit board, and more particularly to a circuit board structure.

### BACKGROUND OF THE DISCLOSURE

When a conventional circuit board is manufactured, the conventional circuit board needs to be formed with at least one blind hole, and the at least one blind hole needs to be further processed by an electroplating process. Since circuit layout of the conventional circuit board becomes more and more dense, an aperture of the blind hole needs to be reduced. That is to say, the blind hole in the conventional circuit board needs to be formed with a high aspect ratio.

However, the electroplating process for the conventional circuit board has some limitations. For example, the electroplating process is limited to an electroplating apparatus, so that the electroplating process is only used for electroplating a blind hole having an aspect ratio less than N (e.g., 1.5). Accordingly, when the blind hole of the conventional circuit board has an aspect ratio larger than N, the blind hole cannot be completely electroplated.

### SUMMARY OF THE DISCLOSURE

In response to the above-referenced technical inadequacies, the present disclosure provides a circuit board structure to effectively improve the issues associated with conventional circuit boards.

In one aspect, the present disclosure provides a circuit board structure, which includes a multi-layer board, a conductive body, and an electroplated layer. The multi-layer board has a predetermined conductive layer embedded therein. The multi-layer board includes a first blind hole recessed in a board surface thereof so as to allow a part of the predetermined conductive layer to be exposed therefrom. The first blind hole has an aperture that is within a range of 0.15-0.5 mm, and the first blind hole has an aspect ratio defined as M that is within a range of 1.5-10. The conductive body is filled in the first blind hole and is electrically coupled to the part of the predetermined conductive layer exposed from the first blind hole. An inner surface of the conductive body defines a second blind hole having an aspect ratio that is less than N, and N is larger than 0 and is less than M. The electroplated layer is formed in the second blind hole and is connected to the inner surface of the conductive body.

In one aspect, the present disclosure provides a circuit board structure, which includes a multi-layer board and a conductive body. The multi-layer board has a predetermined conductive layer embedded therein. The multi-layer board includes a first blind hole recessed in a board surface thereof so as to allow a part of the predetermined conductive layer to be exposed therefrom. The first blind hole has an aperture that is within a range of 0.15-0.5 mm, and the first blind hole has an aspect ratio defined as M that is within a range of 1.5-10. The conductive body is filled in the first blind hole and is electrically coupled to the part of the predetermined conductive layer exposed from the first blind hole. An inner surface of the conductive body defines a second blind hole having an aspect ratio that is less than N, and N is larger than 0 and is less than M.

In one aspect, the present disclosure provides a circuit board structure, which includes a multi-layer board and a conductive body. The multi-layer board has a predetermined conductive layer embedded therein. The multi-layer board includes a first blind hole recessed in a board surface thereof so as to allow a part of the predetermined conductive layer to be exposed therefrom. The first blind hole has an aperture that is within a range of 0.15-0.5 mm, and the first blind hole has an aspect ratio defined as M that is within a range of 1.5-10. The conductive body is filled in the first blind hole and is electrically coupled to the part of the predetermined conductive layer exposed from the first blind hole.

Therefore, since the circuit board structure of the present disclosure is formed with the conductive body in the first blind hole of the multi-layer board, the aspect ratio of any blind hole in the multi-layer board is not limited to the electroplating ability of the conventional electroplating apparatus any longer.

Specifically, the circuit board structure of the present disclosure is formed with the conductive body in the first blind hole of the multi-layer board, so that the second blind hole having a smaller aspect ratio can be formed to replace the first blind hole by the conductive body, and the conventional electroplating apparatus can be used to electroplate the multi-layer board having the first blind hole that is over the electroplating ability of the conventional electroplating apparatus.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a cross-sectional view showing step S110 of a manufacturing method of a circuit board structure according to a first embodiment of the present disclosure.

FIG. 2A and FIG. 2B are cross-sectional views showing step S130 of the manufacturing method of the circuit board structure according to the first embodiment of the present disclosure.

FIG. 3 is a cross-sectional views showing step S150 of the manufacturing method of the circuit board structure according to the first embodiment of the present disclosure.

FIG. 4A and FIG. 4B are cross-sectional views showing steps S170 and S190 of the manufacturing method of the circuit board structure according to the first embodiment of the present disclosure.

FIG. 5 is a cross-sectional views showing step S140 of the manufacturing method of the circuit board structure according to the first embodiment of the present disclosure.

FIG. 6 and FIG. 7 are cross-sectional views showing the manufacturing method of the circuit board structure after implementing step S140 according to the first embodiment of the present disclosure.

FIG. 8 is a cross-sectional view showing step S230 of a manufacturing method of a circuit board structure according to a second embodiment of the present disclosure.

FIG. 9 is a cross-sectional view showing step S250 of the manufacturing method of the circuit board structure according to the second embodiment of the present disclosure.

FIG. 10 is a cross-sectional view showing steps S270 and S290 of the manufacturing method of the circuit board structure according to the second embodiment of the present disclosure.

FIG. 11 is a cross-sectional view showing step S240 of the manufacturing method of the circuit board structure according to the second embodiment of the present disclosure.

FIG. 12 is a cross-sectional view showing the manufacturing method of the circuit board structure after implementing step S240 according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

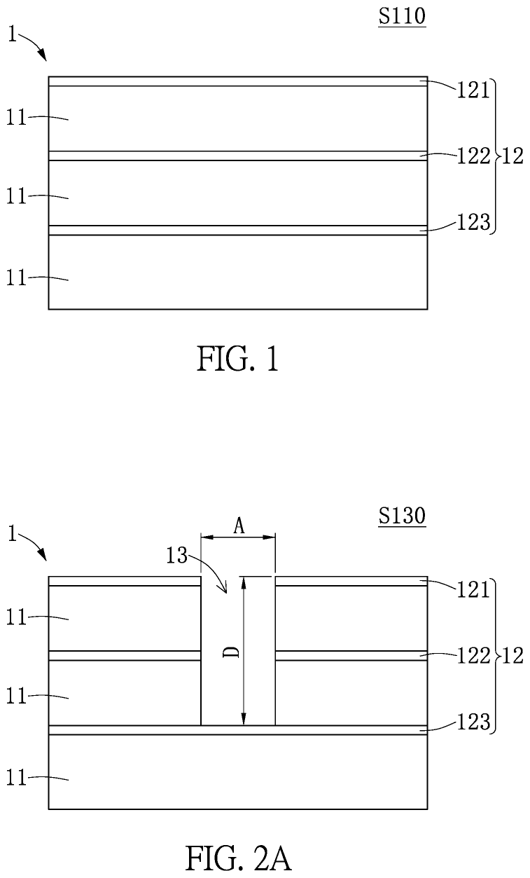

Referring to FIG. 1 to FIG. 7, a first embodiment of the present disclosure provides a circuit board structure and a manufacturing method thereof. The circuit board structure in the present embodiment is manufactured by implementing the manufacturing method, but the present disclosure is not limited thereto. For example, in other embodiments of the present disclosure, the circuit board structure can be manufactured by implementing other manufacturing methods.

Moreover, in order to realize the circuit board structure of the present embodiment, the following description discloses the manufacturing method, and then discloses the circuit board structure. The manufacturing method in the present embodiment adapts the conventional electroplating process (or the conventional electroplating apparatus) that is used for electroplating a blind hole having an aspect ratio less than N. However, the manufacturing method in the present embodiment can be implemented to electroplate a blind hole having an aspect ratio larger than N by adapting the conventional electroplating process. N is preferably within a range of 1-1.5, but the present disclosure is not limited thereto. For example, in other embodiments of the present disclosure, N can be larger than 1.5.

It should be noted that, the drawings just show a related portion of the circuit board structure for the sake of brevity. As shown in FIG. 1 to FIG. 4B, the manufacturing method includes a preparing step S110, a drilling step S130, a filling step S150, a hardening step S170, and an electroplating step S190. However, the manufacturing method of the present disclosure is not limited to the above steps.

For example, in other embodiments of the present disclosure, the steps S110 to S190 can be changed, canceled, or added according to design requirements. In addition, the following description sequentially discloses the steps S110 to S190 of the manufacturing method.

As shown in FIG. 1, the preparing step S110 is implemented by providing a multi-layer board 1. The multi-layer board 1 includes a plurality of boards 11 and a plurality of conductive layers 12 disposed on the boards 11. In the present embodiment, the number of the boards 11 and the number of the conductive layers 12 of the multi-layer board 1 each can be three, but the present disclosure is not limited thereto. One of the conductive layers 12 embedded in the multi-layer board 1 is defined as a predetermined conductive layer 123.

In other words, the multi-layer board 1 in the present embodiment includes a first conductive layer 121 and a second conductive layer 122 arranged between the first conductive layer 121 and the predetermined conductive layer 123. An outer surface of the first conductive layer 121 is defined as a board surface of the multi-layer board 1.

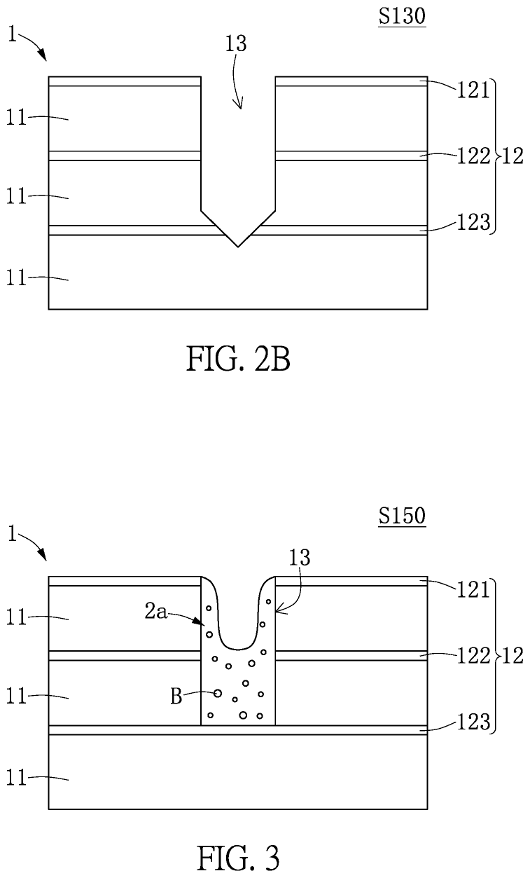

As shown in FIG. 2A, the drilling step S130 is implemented by drilling from the board surface of the multi-layer board 1 (e.g., the outer surface of the first conductive layer 121 shown in FIG. 2A) to the predetermined conductive layer 123 so as to form a first blind hole 13. The first blind hole 13 has an aperture A that is within a range of 0.15-0.5 mm, and the first blind hole 13 has an aspect ratio defined as M that is equal to a depth D of the first blind hole 13 divided by the aperture A. Specifically, M is larger than N, and M can be within a range of 1.5-10. In the present embodiment, the aperture A of the first blind hole 13 is substantially within a range of 0.2-0.3 mm, and M is within a range of 3-5.

Moreover, the drilling step S130 can be implemented by using a mechanical drilling manner to drill from the board surface of the multi-layer board 1, and then using a laser drilling manner so as to form the first blind hole 13, in which a portion of the predetermined conductive layer 123 is exposed from the first blind hole 13. The portion of the predetermined conductive layer 123 shown in FIG. 2A is exposed from the first blind hole 13 by using the laser drilling manner, thereby effectively preventing the mechanical drilling manner from damaging the portion of the predetermined conductive layer 123. A bottom of the first blind hole 13 (i.e., the portion of the predetermined conductive layer 123) can be in a flat shape, but the present disclosure is not limited thereto.

For example, as shown in FIG. 2B, the drilling step S130 can be implemented only by using a mechanical drilling manner to drill from the board surface of the multi-layer board 1 so as to form the first blind hole 13 and the portion of the predetermined conductive layer 123 exposed from the first blind hole 13. Accordingly, the predetermined conductive layer 123 is drilled by the mechanical drilling manner, so that the portion of the predetermined conductive layer 123 is a rupture surface, and a bottom of the first blind hole 13 is substantially in a conical shape.

As shown in FIG. 3, the filling step S150 is implemented by filling a conductive paste 2a in the first blind hole 13, in which the first blind hole 13 is preferably not fully filled with the conductive paste 2a. The conductive paste 2a has a low viscosity, and can be a B-stage paste. In the present embodiment, the conductive paste 2a can be a conductive silver paste, a conductive copper paste, a conductive tin paste, or a solder. The conductive paste 2a can include a resin and a conductive material mixed in the resin, but the present disclosure is not limited thereto. For example, if the conductive paste 2a is a conductive tin paste, the conductive paste 2a excludes the resin. In addition, the filling step S150 can be implemented by using a vacuum printing manner.

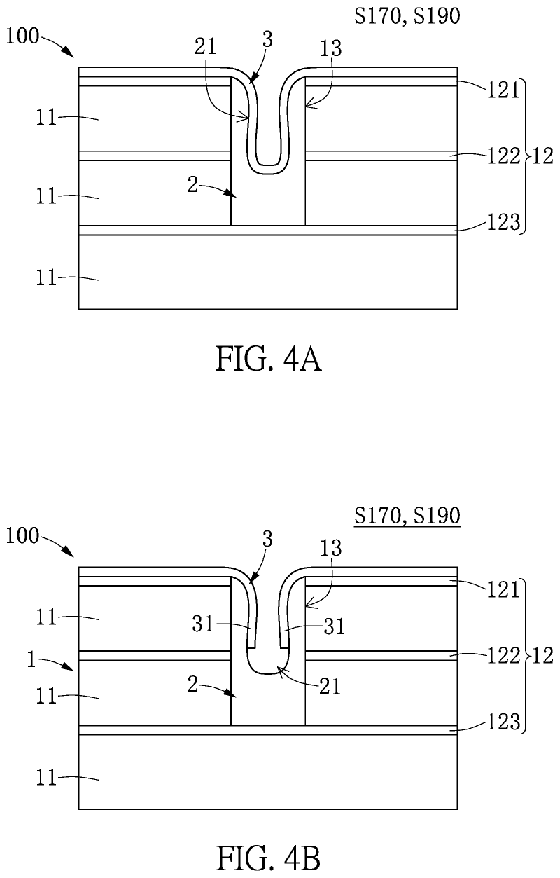

As shown in FIG. 4A and FIG. 4B, the hardening step S170 is implemented by hardening the conductive paste 2a to form a conductive body 2 that is connected to an inner wall defining the first blind hole 13 and is electrically coupled to the predetermined conductive layer 123. A second blind hole 21 having an aspect ratio less than N is formed in the first blind hole 13 by forming the conductive body 2. That is to say, an inner surface of the conductive body 2 defines the second blind hole 21.

It should be noted that, the hardening step S170 of the present embodiment is implemented by baking the conductive paste 2a, so that the conductive paste 2a can be hardened to form the conductive body 2, and bubbles B in the conductive paste 2a can be removed from the conductive paste 2a. The hardening manner of the conductive paste 2a can be changed according to design requirements. The conductive paste 2a can be provided with or without the bubbles B. In other embodiments of the present disclosure, the conductive paste 2a is provided without any bubbles B, the hardening step S170 is implemented by baking the conductive paste 2a for only hardening the conductive paste 2a to form the conductive body 2.

In other words, the material of the conductive body 2 is substantially identical to that of the conductive paste 2a, and the conductive body 2 includes a resin and a conductive material mixed in the resin, but the present disclosure is not limited thereto. For example, if the conductive body 2 is formed by hardening a conductive tin paste, the conductive body 2 excludes the resin.

As shown in FIG. 4A and FIG. 4B, the electroplating step S190 is implemented by applying the conventional electroplating process to the multi-layer board 1 and the conductive body 2 so as to form an electroplated layer 3 that is in the second blind hole 21 and is connected to the conductive body 2. The electroplated layer 3 is electrically coupled to the predetermined conductive layer 123 through the conductive body 2.

Specifically, the electroplating step S190 of the present embodiment can be implemented to form the electroplated layer 3 onto entire of the inner surface of the conductive body 2 (as shown in FIG. 4A) or to form a plurality of electroplated portions 31 of the electroplated layer 3 onto part of the inner surface of the conductive body 2 (as shown in FIG. 4B) according to design requirements, but the present disclosure is not limited thereto.

It should be noted that, since the second conductive layer 122 includes a part of the inner wall, the conductive body 2 can be electrically coupled to the second conductive layer 122 by being connected to the inner wall defining the first blind hole 13. Moreover, the electroplated layer 3 is not only formed on the inner surface of the conductive body 2, but also formed on the first conductive layer 121 for establishing an electrical connection there-between. Moreover, the electroplated layer 3 can be electrically coupled to the predetermined conductive layer 123 and the second conductive layers 122 through the conductive body 2.

In summary, after the steps S110 to S190 of the manufacturing method are implemented, a circuit board structure 100 is suitable for forming a circuit layout with high density can be manufactured, but the circuit board structure 100 is not limited to be manufactured by implementing the steps S110 to S190.

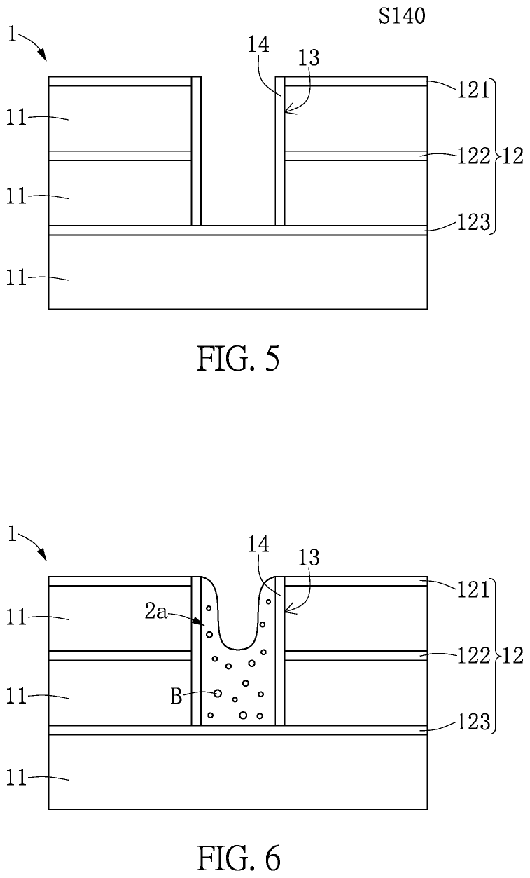

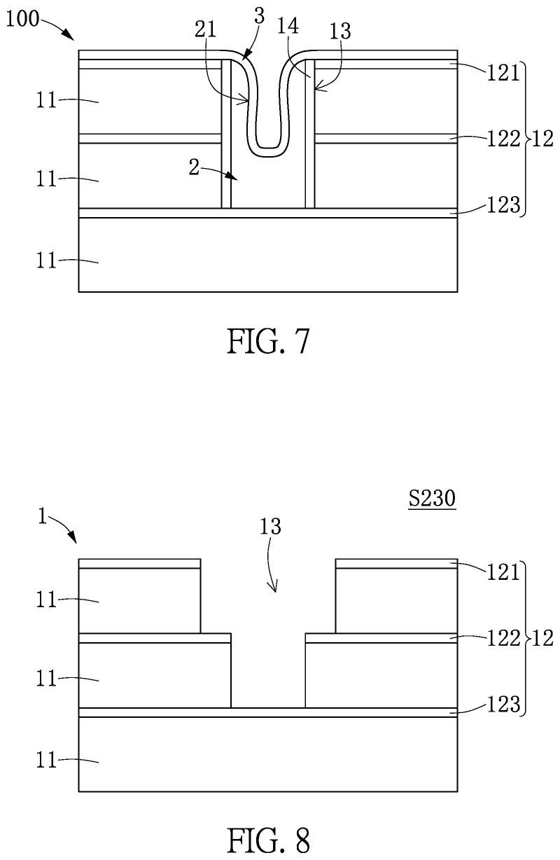

For example, as shown in FIG. 5 to FIG. 7, the manufacturing method can further include a surface treatment step S140 between the drilling step S130 and the filling step S150. Specifically, as shown in FIG. 5, the surface treatment step S140 is implemented by applying a modifying process, a roughing process, or a chemical cooper process to the inner wall defining the first blind hole 13, so that the conductive body 2 formed in the hardening step S170 is connected to the inner wall that is modified by the surface treatment step S140 (as shown in FIG. 7). For example, the multi-layer board 1 has a modification layer 14 formed on the inner wall defining the first blind hole 13, and the modification layer 14 is electrically conductive and is entirely covered by the conductive body 2.

The following description discloses the circuit board structure 100, and the drawings just show a related portion of the circuit board structure 100 for the sake of brevity. As shown in FIG. 4A and FIG. 4B, the circuit board structure 100 in the present embodiment includes multi-layer board 1, a conductive body 2 arranged in the multi-layer board 1, and an electroplated layer 3 formed on the conductive body 2.

The multi-layer board 1 has a predetermined conductive layer 123 embedded therein. The multi-layer board 1 includes a first blind hole 13 recessed in a board surface thereof so as to allow a part of the predetermined conductive layer 123 to be exposed therefrom. The first blind hole 13 has an aperture A that is within a range of 0.15-0.5 mm, and the first blind hole 13 has an aspect ratio defined as M that is within a range of 1.5-10. In the present embodiment, the aperture A of the first blind hole 13 is within a range of 0.2-0.3 mm, and M is within a range of 3-5.

The conductive body 2 is filled in the first blind hole 13 and is electrically coupled to the part of the predetermined conductive layer 123 exposed from the first blind hole 13. An inner surface of the conductive body 2 defines a second blind hole 21 having an aspect ratio that is less than N. N is larger than 0 and is less than M. N is preferably within a range of 1-1.5. Specifically, the conductive body 2 is electrically coupled to the predetermined conductive layer 123 by being connected to the portion of the predetermined conductive layer 123 exposed from the first blind hole 13.

The electroplated layer 3 is formed in the second blind hole 21 and is connected to the inner surface of the conductive body 2. The electroplated layer 3 is electrically coupled to the predetermined conductive layer 123 through the conductive body 2. As shown in FIG. 4A, the electroplated layer 3 is formed on entire of the inner surface of the conductive body 2. As shown in FIG. 4B, the electroplated layer 3 includes two electroplated portions 31 spaced apart from each other and formed on the inner surface of the conductive body 2, and the two electroplated portions 31 are electrically coupled to each other through the conductive body 2.

In addition, in other embodiments of the present disclosure, the electroplated layer 3 of the circuit board structure 100 can be omitted according to design requirements. In other words, the circuit board structure 100 can include the multi-layer board 1 and the conductive body 2 arranged in the multi-layer board 1, and the conductive body 2 is formed without the second blind hole 21.

### Second Embodiment

Referring to FIG. 8 to FIG. 12, a second embodiment of the present disclosure provides a circuit board structure and a manufacturing method thereof. The present embodiment is similar to the first embodiment, so that the same features of the two embodiments (e.g., the preparing step) are not disclosed in the following description, and the difference between the two embodiments is disclosed as follows.

As shown in FIG. 8, after the drilling step S230 is implemented, a portion of the second conductive layer 122 is exposed from the first blind hole 13, and an inner wall defining the first blind hole 13 is in a step shape. In other words, the portion of the second conductive layer 122 exposed from the first blind hole 13 is a step surface.

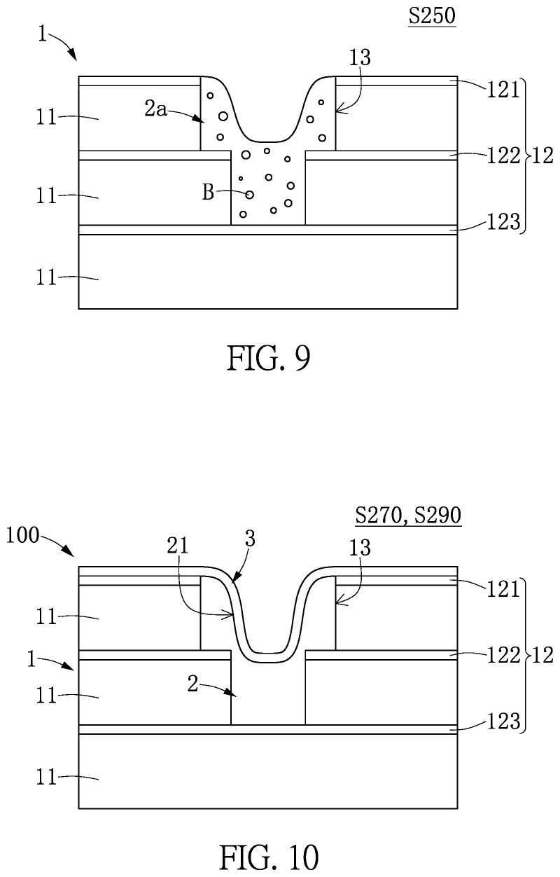

As shown in FIG. 9, the filling step S250 is implemented by filling a conductive paste 2a in the first blind hole 13. Specifically, the portion of the predetermined conductive layer 123 and the portion of the second conductive layer 122 both exposed from the first blind hole 13 are embedded in the conductive paste 2a, and the first blind hole 13 is preferably not fully filled with the conductive paste 2a.

As shown in FIG. 10, after the hardening step S270 is implemented, the conductive body 2 is connected to the inner wall defining the first blind hole 13. In other words, the conductive body 2 is connected to the portion of the predetermined conductive layer 123 and the portion of the second conductive layer 122 both exposed from the first blind hole 13, so that the conductive body 2 is electrically coupled to the predetermined conductive layer 123 and the second conductive layer 122.

As shown in FIG. 10, after the electroplating step S290 is implemented, the electroplated layer 3 is connected to the first conductive layer 121 and the inner surface of the conductive body 2, so that the electroplated layer 3 is electrically coupled to the predetermined conductive layer 123 and the second conductive layer 122 through the conductive body 2.

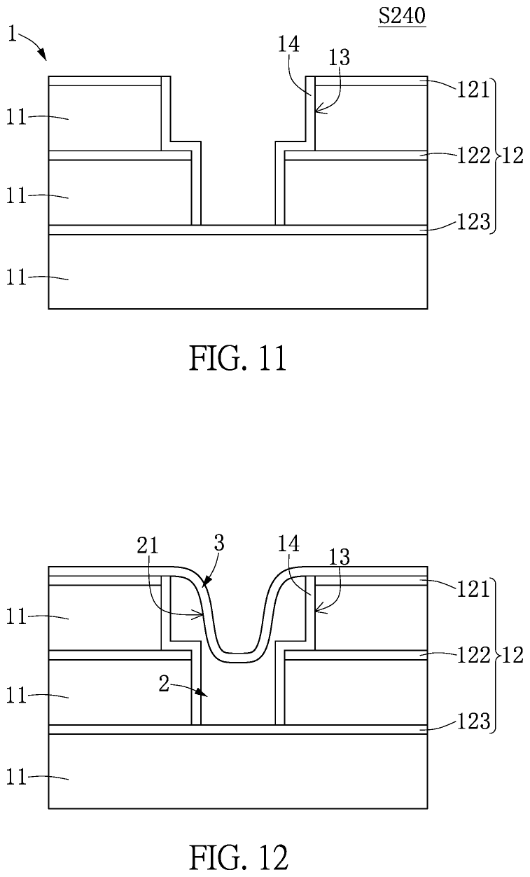

In addition, as shown in FIG. 11 and FIG. 12, the manufacturing method of the present embodiment can further include a surface treatment step S240 between the drilling step S230 and the filling step S250. Specifically, the surface treatment step S240 is implemented by applying a modifying process, a roughing process, or a chemical cooper process to the inner wall defining the first blind hole 13, so that the conductive body 2 formed in the hardening step S270 is connected to the inner wall that is modified by the surface treatment step S240.

Moreover, the circuit board structure 100 of the present embodiment is substantially disclosed in the above description.

In conclusion, the circuit board structure 100 of the present disclosure is formed with the conductive body 2 in the first blind hole 13 of the multi-layer board 1, so that the second blind hole 21 having a smaller aspect ratio can be formed to replace the first blind hole 13 by the conductive body 2, and the conventional electroplating apparatus can be used to electroplate the multi-layer board 1 having the first blind hole 13 that is over the electroplating ability of the conventional electroplating apparatus.

In other words, since the circuit board structure 100 of the present disclosure is formed with the conductive body 2 in the first blind hole 13 of the multi-layer board 1, the aspect ratio of any blind hole in the multi-layer board 1 can be not limited to the electroplating ability of the conventional electroplating apparatus.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

1. A circuit board structure, comprising:
a multi-layer board having a predetermined conductive layer embedded therein, wherein the multi-layer board includes a first blind hole recessed in a board surface thereof so as to allow a part of the predetermined conductive layer to be exposed therefrom, the first blind hole has an aperture having a diameter that is within a range of 0.15-0.5 mm, and the first blind hole has an aspect ratio defined as M that is within a range of 1.5-10;
a hardened conductive paste filled in the first blind hole and electrically coupled to the part of the predetermined conductive layer exposed from the first blind hole, wherein an inner surface of the hardened conductive paste defines a second blind hole having an aspect ratio that is less than N, and N is larger than 0 and is less than M; and
an electroplated layer formed in the second blind hole and connected to the inner surface of the hardened conductive paste.

2. The circuit board structure according to claim 1, wherein the multi-layer board has a modification layer formed on an inner wall defining the first blind hole, and the modification layer is entirely covered by the hardened conductive paste.

3. The circuit board structure according to claim 1, wherein the electroplated layer is formed on entire of the inner surface of the hardened conductive paste.

4. The circuit board structure according to claim 1, wherein the electroplated layer includes two electroplated portions spaced apart from each other and formed on the inner surface of the hardened conductive paste, and the two electroplated portions are electrically coupled to each other through the hardened conductive paste.

5. The circuit board structure according to claim 1, wherein the multi-layer board includes a first conductive layer disposed on the board surface and a second conductive layer arranged between the first conductive layer and the predetermined conductive layer, a portion of the second conductive layer is exposed from the first blind hole, and an inner wall defining the first blind hole is in a step shape, and wherein the portion of the second conductive layer exposed from the first blind hole is covered by the hardened conductive paste, and the electroplated layer is connected to the first conductive layer.

6. The circuit board structure according to claim 1, wherein N is within a range of 1-1.5, the aperture of the first blind hole is within a range of 0.2-0.3 mm, and M is within a range of 3-5.

7. The circuit board structure according to claim 1, wherein the hardened conductive paste includes a resin and a conductive material mixed in the resin.

8. A circuit board structure, comprising:
a multi-layer board having a predetermined conductive layer embedded therein, wherein the multi-layer board includes a first blind hole recessed in a board surface thereof so as to allow a part of the predetermined conductive layer to be exposed therefrom, the first blind hole has an aperture having a diameter that is within a range of 0.15-0.5 mm, and the first blind hole has an aspect ratio defined as M that is within a range of 1.5-10; and
a hardened conductive paste filled in the first blind hole and electrically coupled to the part of the predetermined conductive layer exposed from the first blind hole, wherein an inner surface of the hardened conductive paste defines a second blind hole having an aspect ratio that is less than N, and N is larger than 0 and is less than M.

9. The circuit board structure according to claim 8, wherein N is within a range of 1-1.5, the aperture of the first blind hole is within a range of 0.2-0.3 mm, and M is within a range of 3-5.

10. A circuit board structure, comprising:
a multi-layer board having a predetermined conductive layer embedded therein, wherein the multi-layer board includes a first blind hole recessed in a board surface thereof so as to allow a part of the predetermined conductive layer to be exposed therefrom, the first blind hole has an aperture having a diameter that is within a range of 0.15-0.5 mm, and the first blind hole has an aspect ratio defined as M that is within a range of 1.5-10; and
a hardened conductive paste filled in the first blind hole and electrically coupled to the part of the predetermined conductive layer exposed from the first blind hole.
